(19) United States
(12) Patent Application Publication
(10) Pub. No.: US 2007/0235867 A1
(43) Pub. Date: Oct. 11, 2007

(54) Field effect transistor with interleaved layout

(76) Inventors: Fuad Bin Haji Mokhtar, Loveland, CO (US); Grant Andrew Ellis, Loveland, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/400,541

(22) Filed: Apr. 6, 2006

(51) Int. Cl. H01L 23/34

(52) U.S. Cl. 257/728

(57) ABSTRACT

According to one embodiment of the present invention, a power amplifier with an interleaved layout is described. The power amplifier can be a monolithic microwave integrated circuit that includes a first transistor structure (e.g., a power transistor) and a second transistor structure that acts as a current reference. The first transistor structure and the second transistor structure are configured to both be disposed in a first region.

### BACKGROUND OF THE INVENTION

Amplifier circuits are useful for many different applications and are found in many electrical systems. Most amplifier circuits (e.g., power amplifiers) include one or more active devices that generate a lot of heat. This heat can cause the performance of transistors in the amplifier to vary with respect to each other in a manner that negatively affects performance of the amplifier. Alternatively, the heat differences between different areas in the circuit can cause one or more transistors in the amplifier to violate design requirements or specifications.

The effects of heat are aggravated when the circuit is made from materials with poor thermal conductivity. For example, Gallium Arsenide (GaAs) integrated circuits offer poor thermal conductivity compared with other substrate materials such as Silicon. For example, when a thermal image of a GaAs power FET (e.g., a single power FET on a die) is taken, a temperature profile reveals that the majority of the heat is confined to the FET structure with very little conducting to the surrounding GaAs substrate. In some cases, the temperature can vary by as much as 39 deg. Celsius or more across the die.

Another challenge is that material properties may vary considerably across the circuit die of the amplifier thereby causing problems similar to the above that were caused by temperature variations. For example, process variations can cause the performance of transistors in the amplifier to vary with respect to each other in a manner that negatively affects performance of the amplifier. Moreover, the process differences between different areas in the circuit die can cause one or more transistors in the amplifier to violate design requirements or specifications.

One goal of amplifier design is the provision of a stable reference bias current. FIG. 10 illustrates a conventional power amplifier design. The amplifier 10 includes a power FET 12 and a current mirror 14. A reference current is useful for stabilizing a field effect transistor's (FET) 12 bias current, which is referred to as IDS, across variations in temperature and/or variations in material parameters. A second FET, referred to as a “current (mirror) reference FET 14” may be used to provide this reference current.

Unfortunately, when the current (mirror) reference FET and the FET requiring a stable bias point do not have the same properties (e.g., ambient temperature, transconductance (gm), or some material property), the reference FET and the FET requiring a stable bias point will have different Vgs versus Ids characteristics. In this example, the power FET 12 is in a first temperature region or zone 11, while the current mirror 14 is in a second temperature region 13. The different VGS versus IDS characteristics result in the reference FET not tracking the FET requiring the stable bias. Stated differently, an unstable bias current (IDS) is generated.

For example, in a simulation that uses a simple current mirror and a simple DC bias, when the DC quiescent bias current for a FET having a gate width equal to 3.9 mm is plotted for several temperatures, the following becomes apparent. For this simulation, a current mirror FET having a gate width size of 110 um is employed. As the difference in temperature between the power FET and the current mirror exceeds 20 degrees C., the current mirror no longer tracks the power FET bias current over the temperature range of 45 degrees C. to 85 degrees C.

Based on the foregoing, there remains a need for a method and apparatus that generates a more stable bias current (IDS) despite process variations and temperature variations that overcomes the disadvantages set forth previously.

### SUMMARY OF THE INVENTION

According to one embodiment of the present invention, a power amplifier with an interleaved layout is described. The power amplifier can be a monolithic microwave integrated circuit that includes a first transistor structure (e.g., a power transistor) and a second transistor structure that acts as a current reference. The first transistor structure and the second transistor structure are configured to both be disposed in a first region.

### BRIEF DESCRIPTION OF THE DRAWINGS

The present invention is illustrated by way of example, and not by way of limitation, in the figures of the accompanying drawings and in which like reference numerals refer to similar elements.

FIG. 1 illustrates a schematic of an actively biased power field effect transistor (FET) according to one embodiment of the invention.

FIG. 2 illustrates a layout of an actively biased power field effect transistor (FET) according to one embodiment of the invention.

FIG. 3 illustrates a reference FET that is separated from the first portion and the second portion of the power FET according to one embodiment of the invention.

FIG. 4 illustrates a reference FET with a width that is greater than the width than the first portion and the second portion of the power FET according to one embodiment of the invention.

FIG. 5 illustrates a reference FET with a width that is less than the width than the first portion and the second portion of the power FET according to one embodiment of the invention.

FIG. 6 illustrates a reference FET that is right shifted with respect to the first portion and the second portion of the power FET according to one embodiment of the invention.

FIG. 7 illustrates a reference FET that is left shifted with respect to the first portion and the second portion of the power FET according to one embodiment of the invention.

FIG. 8 illustrates a layout of an actively biased power field effect transistor (FET) according to a second embodiment of the invention.

FIG. 9 is a flowchart illustrating a method for fabricating the biasing circuit according to one embodiment of the invention.

FIG. 10 illustrates a conventional power amplifier design.

### DETAILED DESCRIPTION

A power field effect transistor (FET) with an interleaved layout is described. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Active Biasing with Current Mirror

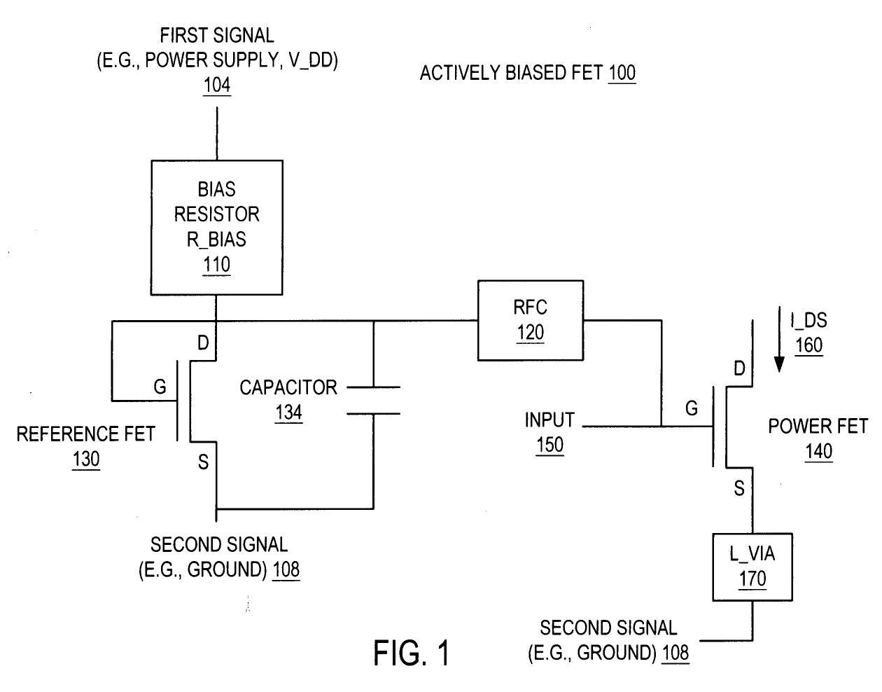

FIG. 1 illustrates a schematic of an actively biased power field effect transistor (FET) 100 according to one embodiment of the invention. In this embodiment, the biasing circuit is implemented with a current mirror circuit that is used to actively bias the power FET. The operation of a current mirror for active biasing is now described. A reference FET 130 is biased using a resistor (Rbias) 110 for a desired Vgs. Due to temperature or processing variations, the quiescent current through the reference FET 130 varies. As a result, an increase in current in the reference FET 130 results in a lower Vgs used to bias the power FET 140, thereby decreasing the power FET current (Ids) 160. A decrease in the reference FET current results in a higher Vgs supplied to the power FET 140, thereby resulting in higher FET current (Ids) 160. This feedback mechanism allows the bias point of the reference FET 130 to track the bias point of the power FET 140 over temperature and process and vica versa. The actively biased FET 100 includes a radio frequency choke (RFC) 120 that provides a high impedance to all RF currents and passes only DC. L_VIA 170 is a substrate via that provides a low-inductance DC and RF signal path to ground. In one embodiment, the value of capacitor 134 may be 10 pF or more. In one embodiment, the bias resistor 110 can be a few 10's of Ohms to a few thousand Ohms. I_DS 160 is typically in the range of about 100 mA to about 1 to 2 Amperes. It is noted that Vgs is typically in the range of about 0.3V to about 0.7V for enhancement mode devices and in the range of about −0.7V to about 0.0V for depletion mode devices.

By positioning or configuring the current mirror and the power FET device in the same location or region, which is referred to herein as a co-location scheme, according to the teachings of the invention, the effects of thermal variations of the device (e.g., self-heating) and material processing variations across the die and wafer on circuit operation are minimized, resulting in a more stable bias operating point.

This invention exploits the interdigital nature of the MMIC FET by co-locating the current mirror FET with the power FET by interleaving them together as a single FET structure. In one embodiment, this configuration results in a smaller circuit layout area.

According to another embodiment, the value of the by-pass capacitor (C) is increased in order to reduce potential interference from the current mirror FET (e.g., potential for cross-talk of power FET to interfere with the current mirror FET). The value of the by-pass capacitor can also be increased when operating the power FET at a lower frequency.

First Interleaved Layout 58

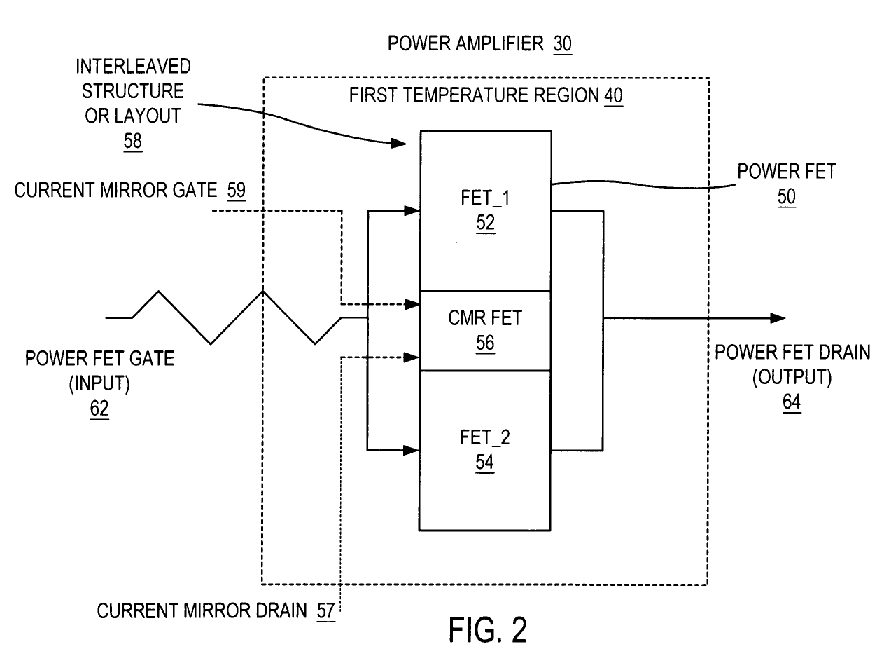

FIG. 2 illustrates a first layout 58 of an actively biased field effect transistor 30 according to one embodiment of the invention. The actively biased field effect transistor 30 includes a power field effect transistor (FET) 50 that includes at least one FET. In one embodiment, the power field effect transistor (FET) 50 includes a first FET (FET_1) 52 and a second FET (FET_2) 54. The FET_1 52 and FET_2 54 each includes a gate portion that is coupled to an input electrode 62. Optionally, the gate portion of FET_1 52 and FET_2 54 can be coupled to input electrode 62 through a resistor. The FET_1 52 and FET_2 54 each also includes a drain portion that is coupled to an output electrode 64. The FET_1 52 and FET_2 54 each also includes a source portion (not shown) that is coupled to a ground plane through vias.

The power field effect transistor (FET) 50 also includes a current mirror reference (CMR) field effect transistor (FET) 56 that includes a gate portion that is coupled to a current mirror gate electrode 59 and a drain portion that is coupled to a current mirror drain electrode 57. The CMR FET 56 also includes a source electrode that is coupled to a ground plane through a via. One novel aspect according to one embodiment of the invention is configuring FET_1 52, CMR FET 56, and FET_2 54 to form an interleaved structure or an interleaved layout 58. Another novel aspect according to another embodiment of the invention is configuring FET_1 52, CMR FET 56, and FET_2 54 in the same region or location (e.g., a first temperature region 40 that has substantially the same temperature or that has a range of temperatures that does not adversely affect the ability of reference FET to track the FET requiring the stable bias) to avoid the problems associated when the power FET and the current mirror reference FET are subject to different temperature conditions as described previously.

In one embodiment, the first layout includes a pseudomorphic high electron mobility transistor (pHEMT) layout for an interleaved power FET. The interleaved power FET includes a reference FET gate and drain connected together to provide a current mirror. The reference FET is “sandwiched” between the power FETs. The drains of the two power FET sections are shown connected at the output.

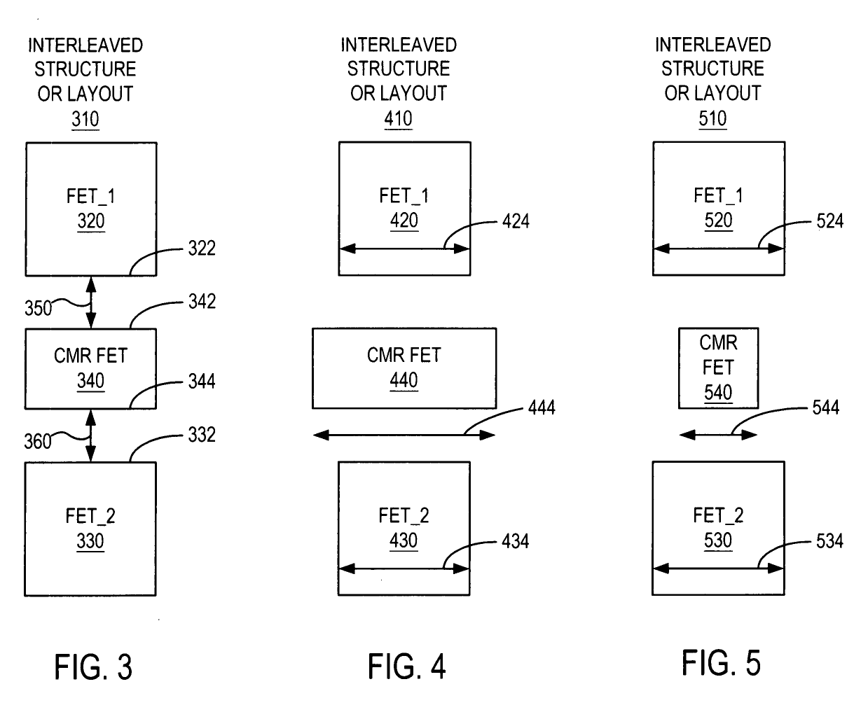

In the embodiment shown in FIG. 2, the FET_1 52 includes a boundary that contacts or touches a boundary of the CMR FET 56. Similarly, the FET_2 54 includes a boundary that contacts or touches a boundary of the CMR FET 56. It is noted that FET_1 52, CMR FET 56, and FET_2 54 need not overlap or touch in other embodiments. For example, referring to FIG. 3, FET_1 320 may be separate from the CMR FET 340. Similarly, FET_2 330 may be separate from the CMR FET 340. In this embodiment, the CMR FET 340 is set apart from FET_1 320 and FET_2 330 by a first predetermined distance 350 and a second predetermined distance 360, respectively. It is noted that FET_1 320 and FET_2 330 can be set apart from CMR FET 340 by the same distance or by a different distance or spacing.

In this embodiment, FET_1 320 includes a first boundary 322 that is set apart by a first predetermined distance 350 from a first boundary 342 of the CMR FET 340. Also, FET_2 330 includes a first boundary 332 that is set apart by a predetermined distance 360 from a second boundary 344 of the CMR FET 340. As noted preivoiusly, the distance 350 and 360 can be the same or different.

Referring to FIG. 4, it is noted that the CMR FET 440 includes a first dimension 444 (e.g., a width). Also, the FET_1 420 includes a first dimension 424 (e.g., a width), and the FET_2 430 includes a first dimension 434 (e.g., a width). In this embodiment, the first dimension 444 of the CMR FET 440 is greater than the first dimension 424 of the FET_1 420 and the first dimension 434 of the FET_2 430. It is noted that the first dimension 424 of the FET_1 420 and the first dimension 434 of the FET_2 430 may be the same or different.

Referring to FIG. 5, it is noted that the CMR FET 540 includes a first dimension 544 (e.g., a width). Also, the FET_1 520 includes a first dimension 524, and the FET_2 530 includes a first dimension 534 (e.g., a width). In this embodiment, the first dimension 544 of the CMR FET 540 is less than the first dimension 524 of the FET_1 520 and the first dimension 534 of the FET_2 530. It is noted that the first dimension 524 of the FET_1 520 and the first dimension 534 of the FET_2 530 may be the same or different.

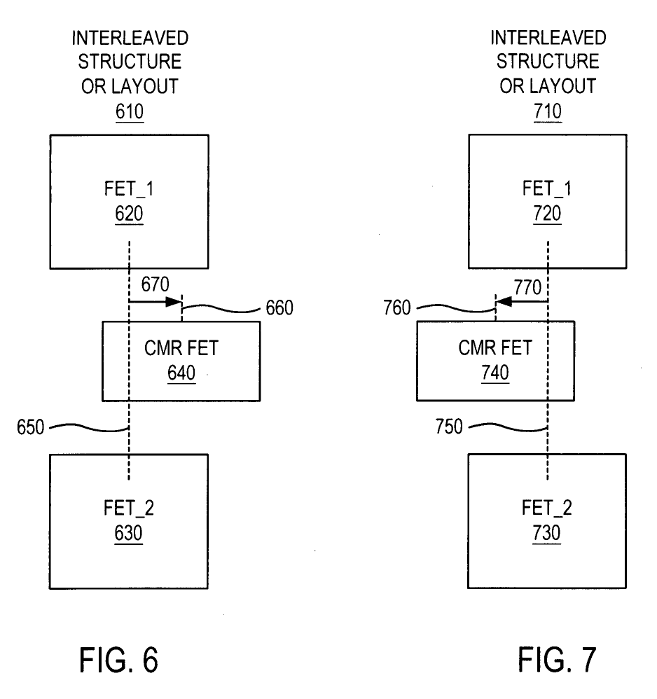

Referring to FIG. 6, it is noted that the FET_1 620 and the FET_2 630 are centered about an imaginary vertical line or axis 650. The CMR FET 640 includes an imaginary center line 660 about which the CMR FET 640 is centered. The imaginary center line 660 of the CMR FET 640 is offset to the right with respect to the imaginary vertical line or axis 650 by a predetermined distance 670.

Referring to FIG. 7, it is noted that the FET_1 720 and the FET_2 730 are centered about an imaginary vertical line or axis 750. The CMR FET 740 includes an imaginary center line 760 about which the CMR FET 740 is centered. The imaginary center line 760 of the CMR FET 740 is offset to the left with respect to the imaginary vertical line or axis 750 by a predetermined distance 770.

Second Interleaved Layout 860

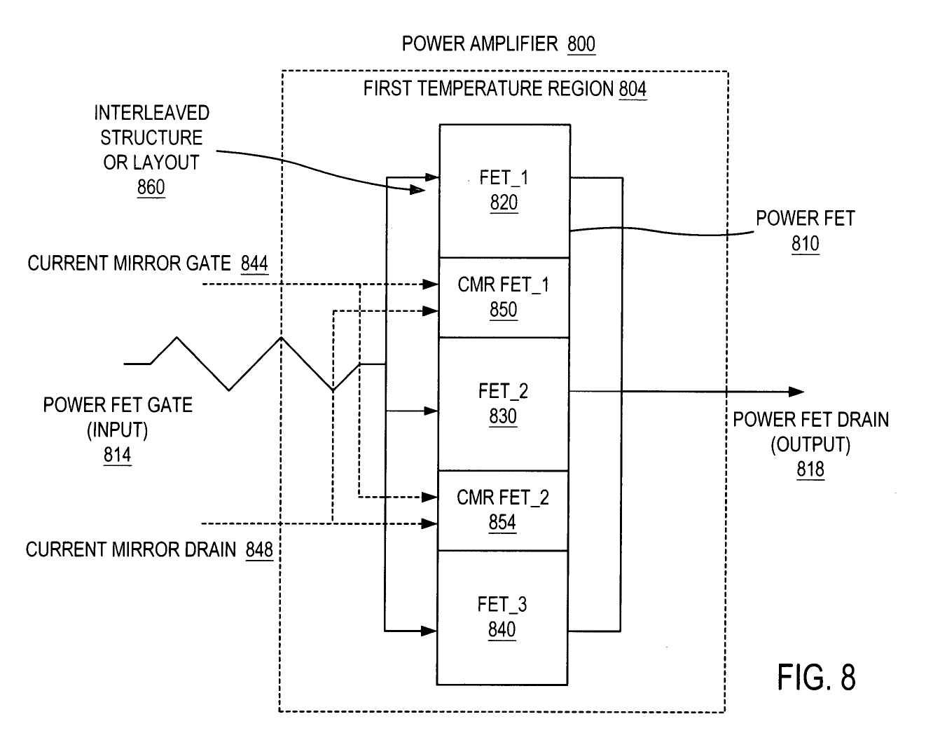

FIG. 8 illustrates a second layout 860 of an actively biased field effect transistor power 800 according to one embodiment of the invention. The actively biased field effect transistor 800 includes a power field effect transistor (FET) 810 that includes at least one FET. In one embodiment, the power field effect transistor (FET) 810 includes a first FET (FET_1) 820, a second FET (FET_2) 830, and a third FET (FET_3) 840.

The FET_1 820, FET_2 830 and FET_3 840 each includes a gate portion that is coupled to an input electrode 814 typically through a resistor. The FET_1 820, FET_2 830 and FET_3 840 each also includes a drain portion that is coupled to an output electrode 818. The FET_1 820, FET_2 830 and FET_3 840 each also includes a source portion (not shown) that is coupled to a ground plane through one or more vias.

The power amplifier 800 also includes a current mirror reference (CMR) field effect transistor (FET)

The first CMR FET 850 (CMR FET_) and the second CMR FET 854 (CMR FET_2) each includes a gate portion that is coupled to a current mirror gate electrode 844 and a drain portion that is coupled to a current mirror drain electrode 848. The first CMR FET 850 (CMR FET_1) and the second CMR FET 854 (CMR FET_2) each also includes a source electrode that is coupled to a ground plane through one or more vias.

It is noted that the number (N) of power FET regions may be varied or adjusted to suit the particular requirements of a specific application. Similarly, the number (M) of current mirror reference FET regions may be varied or adjusted to suit the particular requirements of a specific application. When the CMR FETs are “sandwiched” or interleaved between the power FETs, the number (M) of CMR FETs and the number (N) of power FETs may be related by the following expression: M=N−1.

One novel aspect according to one embodiment of the invention is configuring FET_1 820, CMR FET_1 850, FET_2 830, CMR FET_2 854, and FET_3 840 to form an interleaved structure or an interleaved layout 860. Another novel aspect according to another embodiment of the invention is configuring FET_1 820, CMR FET_1 850, FET_2 830, CMR FET_2 854, and FET_3 840 in the same temperature region (e.g., first temperature region 804) to avoid the problems associated when the power FET and the current mirror reference FET are subject to different temperature conditions as described previously.

In one embodiment, the first layout includes a pHEMT layout for an interleaved power FET. The interleaved power FET includes a reference FET gate and drain connected together to provide a current mirror. The reference FET is “sandwiched” between the power FETs. The drains of the two power FET sections are shown connected at the output.

FIG. 8 illustrates a second layout of an actively biased field effect transistor (FET) according to another embodiment of the invention. For applications requiring very large power FET's that occupy a large surface area, the temperature and/or material properties may vary significantly across the device. In this case, it may be advantageous to use a distributed or segmented current mirror in order to track the average properties of the power FET. FIG. 8 illustrates the interleaved distributed power FET. In this embodiment, two reference FETs are interleaved between three power FET sections. It is noted that the gates and drains of both reference FETs are connected near the input to the power FET.

In one embodiment, the actively biased field effect transistor (FET) according to invention is implemented in a power amplifier that includes an input tuning network and an output tuning network.

Processing

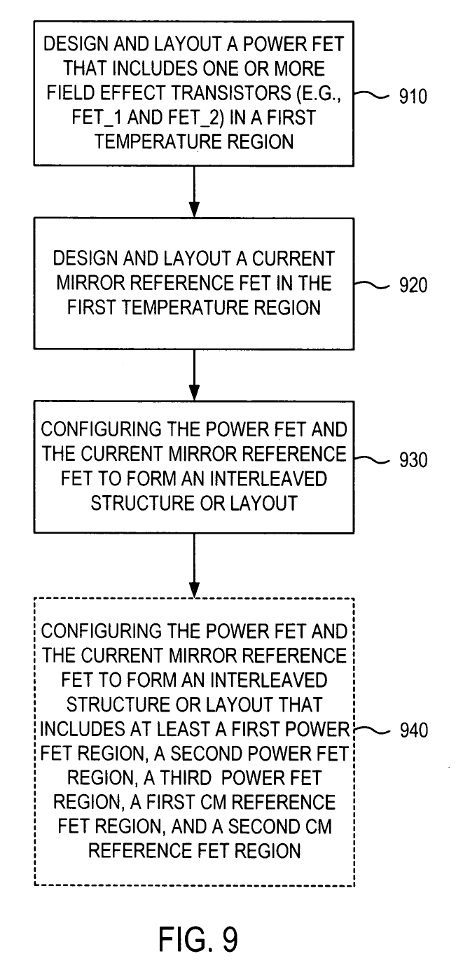

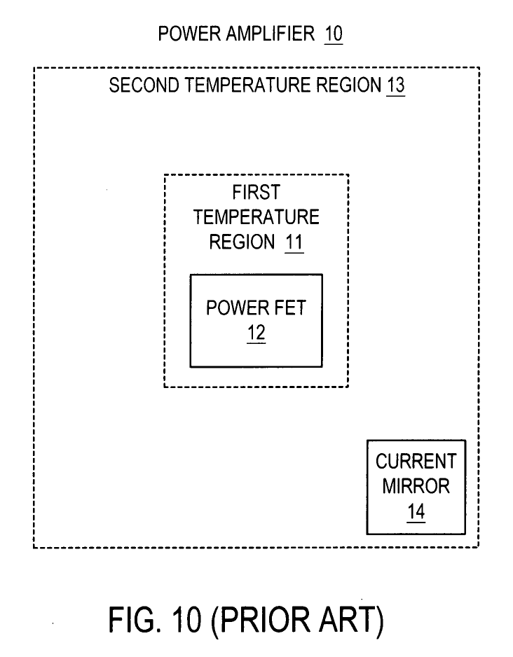

FIG. 9 is a flowchart illustrating a method for manufacturing the power amplifier with an interleaved layout according to one embodiment of the invention. In step 910, a power FET is designed that includes one or more power field effect transistors (e.g., FET_1 and FET_2) in a first temperature region. Step 910 can include the design and layout of the power FET. In step 920, a current mirror reference FET is designed in the first temperature region. Step 920 can include the design and layout of the current mirror reference FET. In step 930, the power FET and the current mirror reference FET are configured to form an interleaved structure or layout. For example, a single CMR FET may be disposed, positioned, or “sandwiched” between two power FET sections. Alternatively, in step 940, when there is more than one CMR FET section and at least three power FET sections, the first CMR FET section and the second CMR FET section may be distributed, respectively, between the first power FET section and the second power FET section and the second power FET section and the third power FET section.

For example, the power FETs and the current mirror reference FETs are configured to form an interleaved structure or layout that includes alternating power FET sections and CMR FET sections. The combination of the power FET and the reference FET is also referred to herein as an actively biased FET.

The following process flow can be utilized to fabricate a monolithic microwave integrated circuit (MMIC) and in particular the power amplifier according to the invention. The circuit can include resistors, capacitors, inductors, air-bridge interconnects, and via holes through the slice. In this example, resistors are formed using conductive GaAs materials. The slice includes an active layer formed on a semi-insulating substrate.

An isolation pattern is formed by using an unannealed ion implant, for example. This step can include the sub-steps of clean slice, spin on resist, align and expose isolation pattern, etch slightly for subsequent alignment, ion implant boron, and strip resist.

The source-drain ohmic contacts are then formed or fabricated. This step of fabricating the source-drain ohmic contacts can include the sub-steps of clean slice, spin on resist, align and expose source-drain pattern, evaporate AuGeNiAu, lift off metal and alloy metallization.

The gate is then fabricated. This step can include the sub-steps of clean slice, spin on resist, E-beam expose gate pattern, recess gates (etch), evaporate TiPtAu, and lift off metal.

A first metallization is formed. This step can include the sub-steps of clean slice, spin on resist, align and expose first metallization pattern that can include inductors, evaporate TiAu, and lift off metal.

A capacitor is then formed. This step can include the sub-steps of clean slice, grow dielectric layer, clean slice, spin on resist, align and expose capacitor top plate pattern, evaporate TiAu, and lift off metal.

A plating sequence is then processed. This step includes the formation of air bridges. This step can include the sub-steps of clean slice, spin on resist, align and expose plating pattern, etch open dielectric, splutter 100 Angstroms TiAu, spin on resist, align and expost air bridge pattern, gold plate, and lift off.

Back side processing is then performed. This processing can include the sub-steps of mounting slice face down and thin to predetermined thickness (e.g., 100 microns), clean slice, spin on resist on back of slice, align and expose via pattern, etch via holes, strip off resist, clean slice, sputter thin TiAu, spin on resist on back of slice, align and expose back side plating pattern, gold plate back side, strip resist and saw slice and separate.

One aspect of the invention is exploiting the interdigital nature of the MMIC FET by co-locating the current mirror FET with the power FET. In one embodiment, the co-location is performed by interleaving the current mirror FET with the power FET together as a single FET. Advantages for doing so include, but are not limited to improved thermal and process tracking of the current mirror bias circuit, a smaller circuit layout area, and enabling smaller reference FETs in current mirror circuits.

The mechanisms and techniques according to the invention may be incorporated into a variety of different electronic devices and systems that include, but are not limited to, amplifiers, power amplifiers, low noise amplifiers, oscillators. Although the mechanisms of the invention have been described herein to mitigate the effects of process variation in a circuit die, and circuits that have sources of large amounts of heat (e.g., circuit die of a power amplifier), it is noted that the mechanisms of the invention may also be useful in other applications or circuits, where there may be a large thermal variation across the circuit. In one application, the configuration of a power amplifier and current mirror according to the invention may be used as a reference for an amplifier that generates low heat, such as a low noise amplifier, but has a large thermal variation across the circuit die.

The teachings according to the invention can be applied to different field effect transistors (FETs), such as a high linearity enhancement-mode pseudomorphic high electron mobility transistor (E-pHEMT) field effect transistor (FET) and depletion-mode high electron mobility, D-pHEMT field effect transistor. In one example, the teachings according to the invention are implemented in a FET that is designed for low noise, high dynamic range operation in wireless infrastructure applications that operate between about 450 MHz and about 6 GHz.

A FET with the configuration and layout according to the invention may be incorporated into the first stage and second stage of front-end low-noise amplifiers (LNAs) and power amplifiers (PAs), in cellular/PCS/WCDMA base stations, a wireless local loop, fixed wireless access, and other high-performance applications.

In the foregoing specification, the invention has been described with reference to specific embodiments thereof. It will, however, be evident that various modifications and changes may be made thereto without departing from the broader scope of the invention. The specification and drawings are, accordingly, to be regarded in an illustrative rather than a restrictive sense.

What is claimed is:

1. A monolithic microwave integrated circuit comprising:
a first transistor structure;
a second transistor structure that acts as a current reference;
wherein the first transistor structure and the second transistor structure are both disposed in a first temperature region.

2. The circuit of claim 1 wherein the first transistor structure includes a first portion and a second portion; and wherein the second transistor structure is interleaved between the first portion and the second portion of the first transistor structure.

3. The circuit of claim 2 wherein the first portion includes a boundary and the second portion includes a boundary; and wherein the second transistor structure includes a first boundary and a second boundary; and wherein one of the boundary of the first portion touches the first boundary of the second transistor structure and the boundary of the second portion touches the second boundary of the second transistor structure.

4. The circuit of claim 1 wherein the first transistor structure includes a first portion and a second portion; and wherein the second transistor structure is set apart a predetermined distance from at least one of the first portion and the second portion of the first transistor structure.

5. The circuit of claim 1 wherein the first transistor structure includes a width; and wherein the second transistor structure includes a width that is substantially the same as the width of the first transistor structure.

6. The circuit of claim 1 wherein the first transistor structure includes a width; and wherein the second transistor structure includes a width that is greater than the width of the first transistor structure.

7. The circuit of claim 1 wherein the first transistor structure includes a width; and wherein the second transistor structure includes a width that is less than the width of the first transistor structure.

8. The circuit of claim 1 wherein the circuit includes a reference line; and wherein the first transistor structure and the second transistor structure are centered with respect to the reference line.

9. The circuit of claim 1 wherein the circuit includes a reference line; and wherein the first transistor structure is centered with respect to the reference line; and wherein the center of the second transistor structure is right shifted by a predetermined distance from the reference line.

10. The circuit of claim 1 wherein the circuit includes a reference line; and wherein the first transistor structure is centered with respect to the reference line; and wherein the second transistor structure is left shifted by a predetermined distance from the reference line.

11. A method for forming an actively biased field effect transistor (FET) comprising:
forming a power field effect transistor (FET) that includes at least one field effect transistor in a first temperature region;
forming a current mirror reference FET in the first temperature region; and
configuring the power FET and the current mirror reference FET to form an interleaved structure.

12. The method of claim 11 wherein the power FET includes at least three sections and the current mirror reference FET includes at least two sections; wherein configuring the power FET and the current mirror reference FET to form an interleaved structure includes
configuring the power FET and the current mirror reference FET to form an interleaved structure that includes alternating layers of the power FET sections and the current mirror reference FET sections.
